(19) United States
(12) Patent Application Publication
(10) Pub. No.: US 2020/0043821 A1
(43) Pub. Date: Feb. 6, 2020

(54) ELECTRONIC ASSEMBLY AND A METHOD OF FORMING THEREOF

(71) Applicant: Avago Technologies International Sales Pte. Limited, Singapore (SG)

(72) Inventors: Deog Soon Choi, Kangseo-Gu (KR); Ah Ron Lee, Dongdaemun-gu (KR)

(21) Appl. No.: 16/049,874

(22) Filed: Jul. 31, 2018

(51) Int. Cl. H01L 23/31; H01L 23/488; H01L 23/00; H05K 1/11

(52) U.S. Cl. CPC H01L 23/3107; H05K 1/11; H01L 24/17; H01L 23/488

(57) ABSTRACT

An electronic assembly includes a substrate having a first surface and a second surface opposing the first surface. The electronic assembly includes first electronic component disposed on the first surface of the substrate, and a first encapsulant encapsulating the first electronic component on the first surface of the substrate. The electronic assembly also includes a second electronic component disposed on the second surface of the substrate, and a second encapsulant encapsulating the second electronic component on the second surface of the substrate such that the second electronic component is completely submerged below a second assembly surface of the second encapsulant. The electronic assembly further includes a groove positioned on the second assembly surface of the second encapsulant, and a solder joint having a portion protruding from the groove for establishing an electrical connection with an external component.

### BACKGROUND

There is increasing demand for smaller electronic devices, particularly with respect to radio frequency (RF) wireless communication products, for example. These products typically include electronic modules (or packages) having various features, such as electronic circuitry and components attached to and/or embedded in a substrate, such as a printed circuit board (PCB), molded compound applied to a surface of the substrate to protect the electrical circuitry and components, and conductive (e.g., metal) pads formed on an opposite surface of the PCB to accommodate subsequent mounting (e.g., using solder) of the modules within the electronic devices, possibly on another external component, such as a mother board or PCB of the electronic devices.

Tighter placement of the components on a substrate is desirable in order to decrease the size of the module, and thus the electronic device containing the module. For example, flip chip dies and surface mount technology (SMT) components are commonly attached to pads on a surface of the substrate. As circuit designs further reduce spaces between various electronic components in RF system-in-package (SIP) modules, for example, the accumulated tolerance of tooling, equipment accuracy and raw materials in a conventional fabrication method is too close to the spaces between the electronic components, making it nearly impossible to further reduce the spaces between electronic components. Also, solder paste used to attach the flip chip and SMT components (as well as other types of components) to the substrate may electrically short after a pick and place process due to the high accumulated tolerance, and solder paste squeezing out from beneath the electronic components may lead to solder electrical shorts after reflow. Currently, attempted solutions include tightening the pick and place accuracy tolerance and force control. However, such solutions are limited by equipment capability, and thus the resulting reduction in accumulated tolerance is minimal.

Accordingly, there is a need to reduce accumulated tolerance, e.g., using existing equipment capability, to enable tighter placement of various components on the substrate or PCB with enhanced reliability.

### BRIEF DESCRIPTION OF THE DRAWINGS

The illustrative embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements throughout the drawings and written description.

FIG. 1A is an illustrative functional block diagram of an electronic assembly in accordance with a representative embodiment.

FIG. 1B is an exploded view of a portion of the illustrative functional block diagram shown in FIG. 1A, in accordance with a representative embodiment.

FIG. 1C is a portion of a bottom view of the illustrative functional block diagram shown in FIG. 1A, in accordance with a representative embodiment.

FIG. 2 is an illustrative cross-sectional view of an electronic assembly in accordance with a representative embodiment.

FIG. 3 is an illustrative cross-sectional view of an electronic module in accordance with another representative embodiment.

FIG. 4 is an illustrative cross-sectional view of a portion of an electronic device in accordance with a representative embodiment.

FIG. 5 shows illustrative cross-sectional views of a method of fabricating an electronic module, according to a representative embodiment.

FIG. 6 is a flow chart depicting a method of fabricating an electronic module, according to a representative embodiment.

FIG. 7 is a flow chart depicting a method of fabricating an electronic module, according to a representative embodiment.

FIG. 8 is a flow chart depicting a method of fabricating an electronic module, according to a representative embodiment.

### DETAILED DESCRIPTION

In the following detailed description, for purposes of explanation and not limitation, example embodiments disclosing specific details are set forth in order to provide a thorough understanding of the present teachings. However, it will be apparent to one of ordinary skill in the art having the benefit of the present disclosure that other embodiments according to the present teachings that depart from the specific details disclosed herein remain within the scope of the appended claims. Moreover, descriptions of well-known apparatuses and methods may be omitted so as to not obscure the description of the example embodiments. Such methods and apparatuses are clearly within the scope of the present teachings.

The terminology used herein is for purposes of describing particular embodiments only, and is not intended to be limiting. The defined terms are in addition to the technical, scientific, or ordinary meanings of the defined terms as commonly understood and accepted in the relevant context.

The terms “a”, “an” and “the” include both singular and plural referents, unless the context clearly dictates otherwise. Thus, for example, “a device” includes one device and plural devices. The terms “substantial” or “substantially” mean to within acceptable limits or degree. The term “approximately” means to within an acceptable limit or amount to one of ordinary skill in the art. Relative terms, such as “above,” “below,” “top,” “bottom,” “upper” and “lower” may be used to describe the various elements” relationships to one another, as illustrated in the accompanying drawings. These relative terms are intended to encompass different orientations of the device and/or elements in addition to the orientation depicted in the drawings. For example, if the device were inverted with respect to the view in the drawings, an element described as “above” another element, for example, would now be below that element. Where a first device is said to be connected or coupled to a second device, this encompasses examples where one or more intermediate devices may be employed to connect the two devices to each other. In contrast, where a first device is said to be directly connected or directly coupled to a second device, this encompasses examples where the two devices are connected together without any intervening devices other than electrical connectors (e.g., wires, bonding materials, etc.).

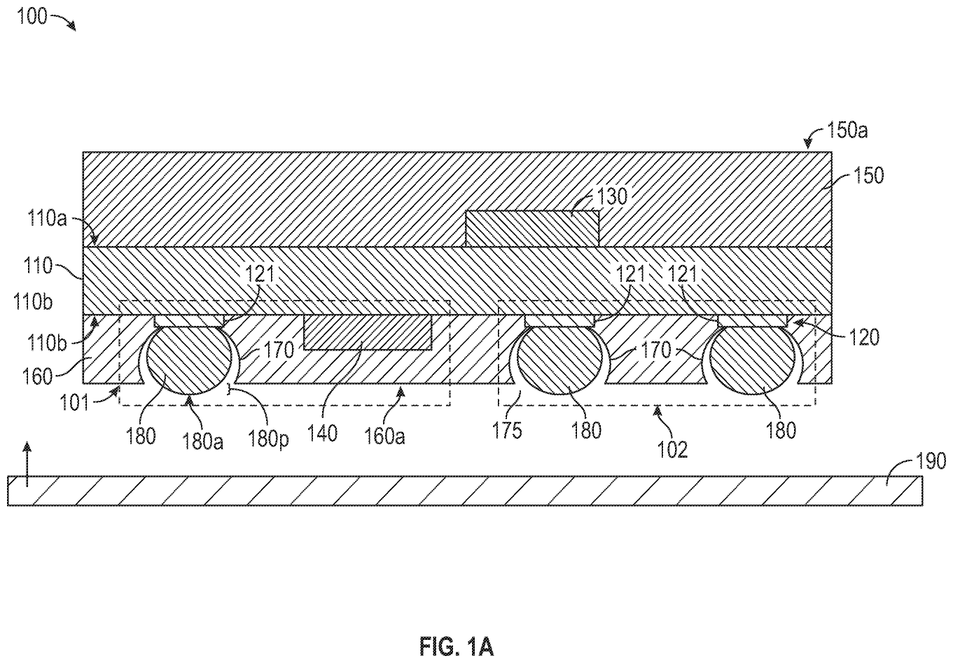

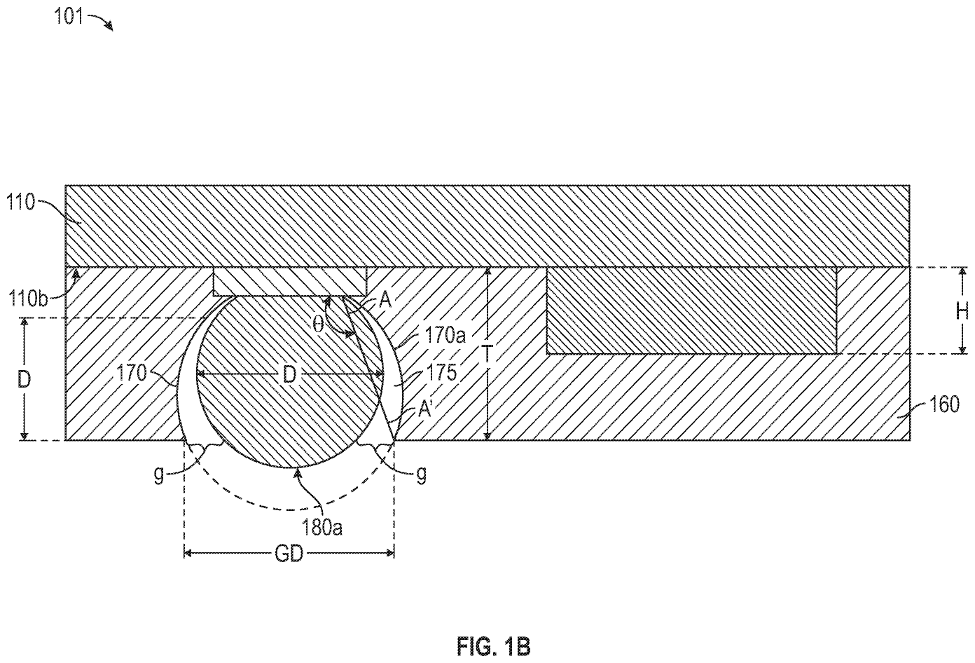

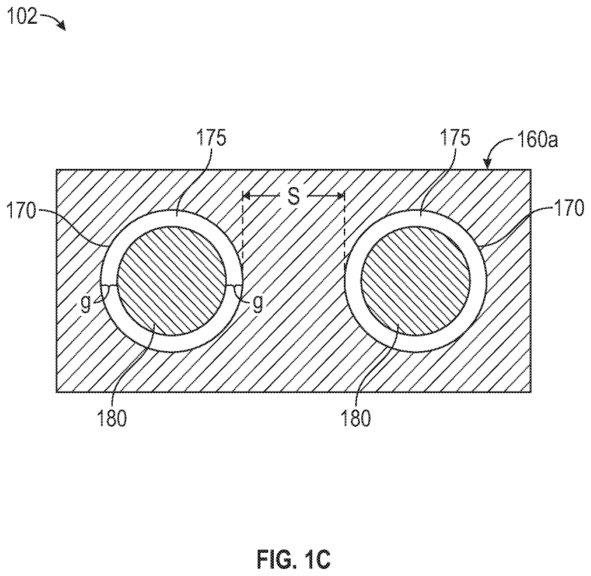

FIG. 1A is an illustrative functional block diagram of an electronic assembly, FIG. 1B is an exploded view of a portion of the illustrative functional block diagram shown in FIG. 1A, and FIG. 1C is a portion of a bottom view of the illustrative functional block diagram shown in FIG. 1A, according to a representative embodiment. The exploded view shown in FIG. 1B corresponds to the portion 101 and the bottom view shown in FIG. 1C corresponds to the portion 102 of FIG. 1A. The illustrative functional block diagram of FIG. 1A, for example, illustrates the functional relationship of various components of an electronic assembly.

Referring to FIG. 1A, an electronic assembly 100 includes a substrate 110 having a top (first) surface 110a and a bottom (second) surface 110b. The substrate 110, for example, may be a printed circuit board (PCB) which may have embedded circuitry (not shown). For purposes of illustration, a first electronic component 130 is mounted on the top surface 110a and a second electronic component 140 is mounted on the bottom surface 110b of the substrate 110. The first electronic component 130 may be electrically connected to the second electronic component 140 through conductive vias and traces (not shown) disposed in the substrate 110. Although FIG. 1A shows the exemplary electronic assembly 100 as having two electronic components, it is understood that the electronic assembly 100 may be optional and may contain different numbers of electronic components without departing from the scope of the present teachings. In one embodiment, the electronic assembly 100 may comprise electronic components 130 or 140 on only one side of the substrate 110.

A first encapsulant 150 is disposed over the top surface 110a of the substrate 110 and substantially encapsulates the first electronic component 130. A second encapsulant 160 is disposed over the bottom surface 110b of the substrate 110 and substantially encapsulates the second electronic component 140. For purpose of illustration, the first encapsulant 150 surrounds the first electronic component 130 such that the first electronic component is completely submerged below a top surface (first assembly surface) 150a of the first encapsulant 150. Similarly, the second encapsulant 160 surrounds the second electronic component 140 such that the second electronic component 140 is completely submerged below a bottom surface (second assembly surface) 160a of the second encapsulant. In other embodiments, the first encapsulant 150 and the second encapsulant 160 may partially surround the first electronic component and the second electronic component, leaving top portions of the first and second electronic components 130 and 140 exposed. In one embodiment, the first electronic components 130 and/or the second electronic components 140 may comprise a plurality of package semiconductor devices stacking on top on one another. The first assembly surface 150a may be configured to allow for further electronic components to be stacked thereon while the second assembly surface 160a may be configured for stacking onto a surface of an external component 190. The first assembly surface 150a and the second assembly surface 160a, for example, comprise a substantially flat assembly surface as shown in FIG. 1A. The substantially flat first assembly surface of the first encapsulant 150 may be configured for receiving an external surface. Similarly, the second assembly surface 160a of the second encapsulant 160 is substantially flat for receiving an external flat surface. The first and second electronic components 130 and 140 on and/or in the substrate 110 are combined and covered with the first and second encapsulants 150 and 160 to form the electronic assembly 100, which in some embodiments may also be referred to as an electronic module. In such case, the substrate 110 may also be referred to as the module substrate.

The first encapsulant 150 and the second encapsulant 160 illustratively include a mold compound that may be formed of a reinforced or non-reinforced resin. The first encapsulant 150, and the second encapsulant 160 are generally to protect the first electronic component 130 and the second electronic component 140, respectively, and to additional structural support to the electronic assembly 100. The mold compound, for example, may include epoxy resin, silicone resin, glass resin, acrylics or polyimides. Other suitable mold compound materials, which are within the purview of one of ordinary skill in the art having had the benefit of the present disclosure, may also be useful.

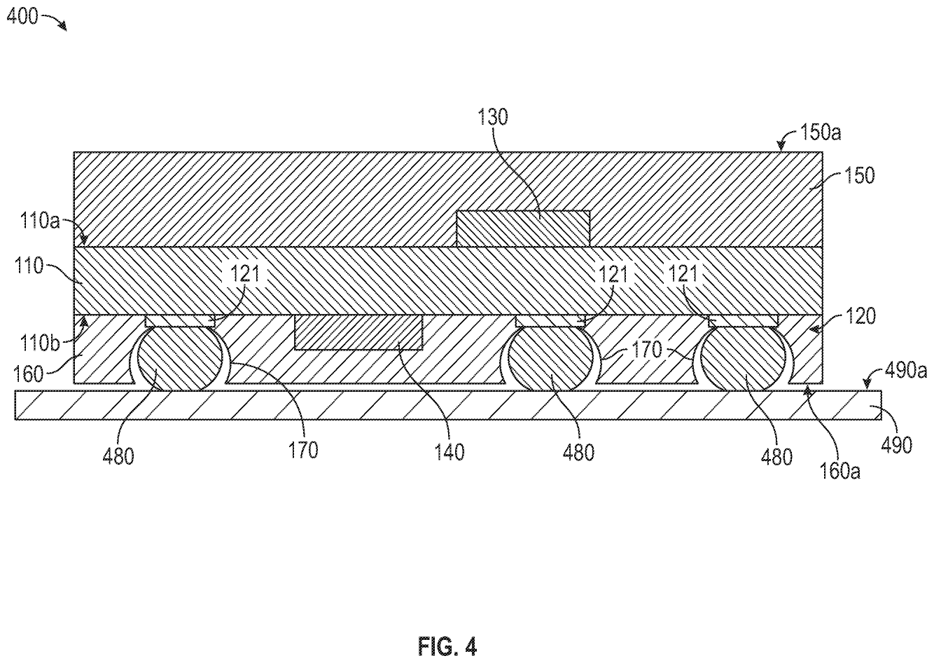

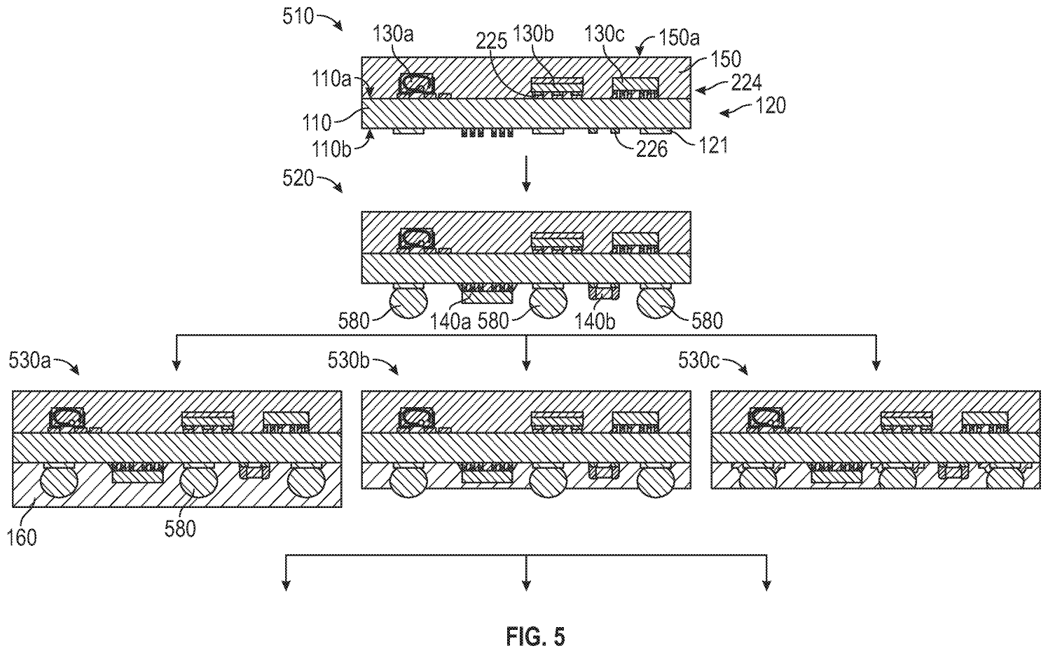

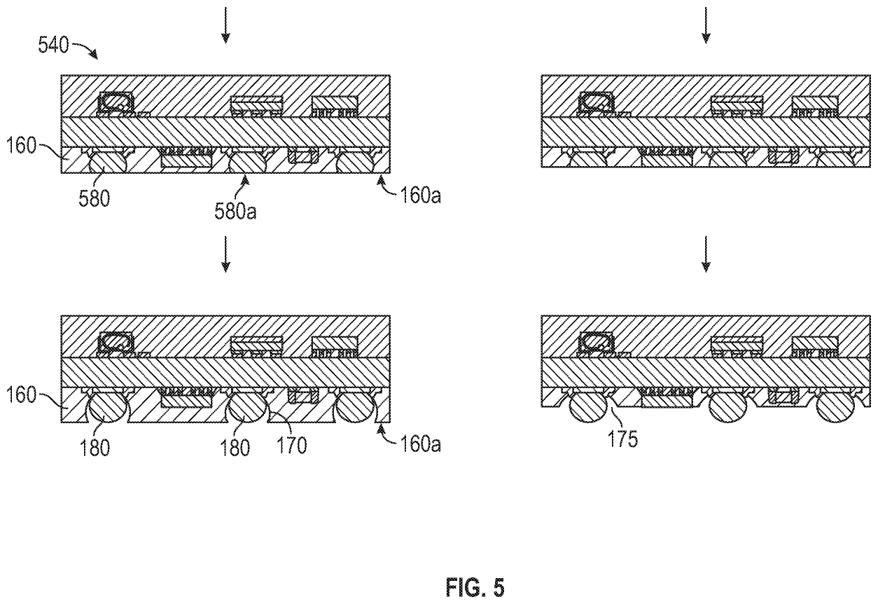

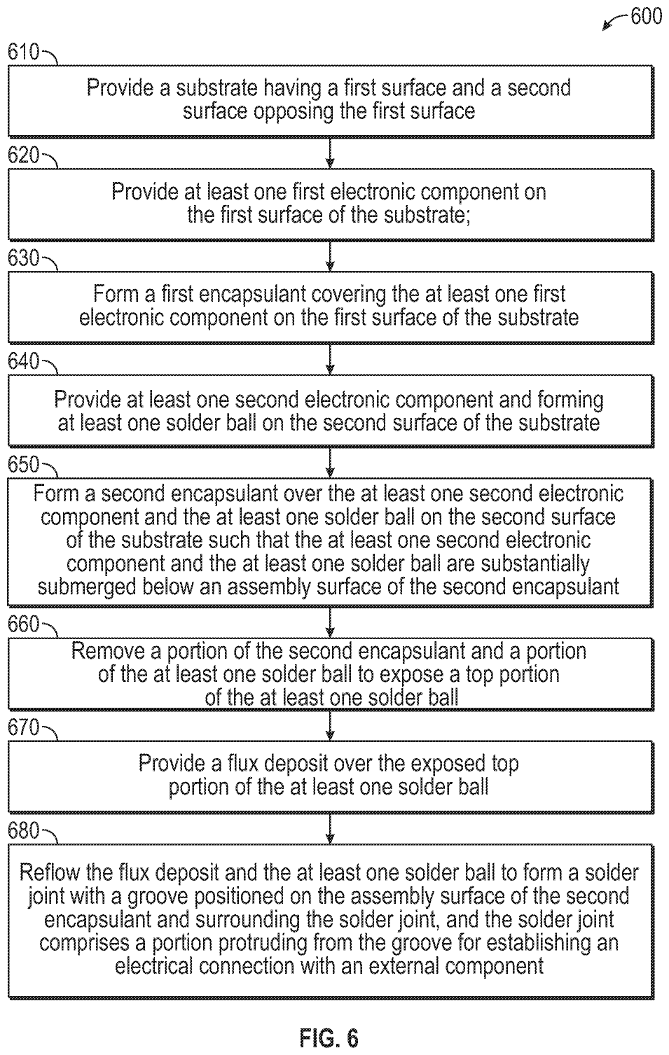

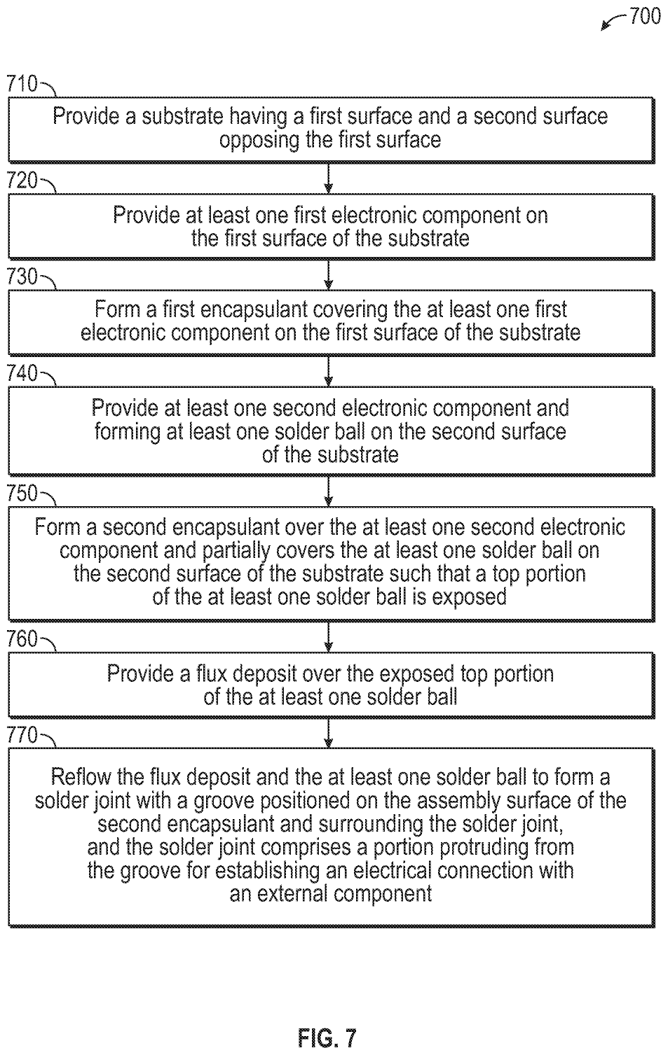

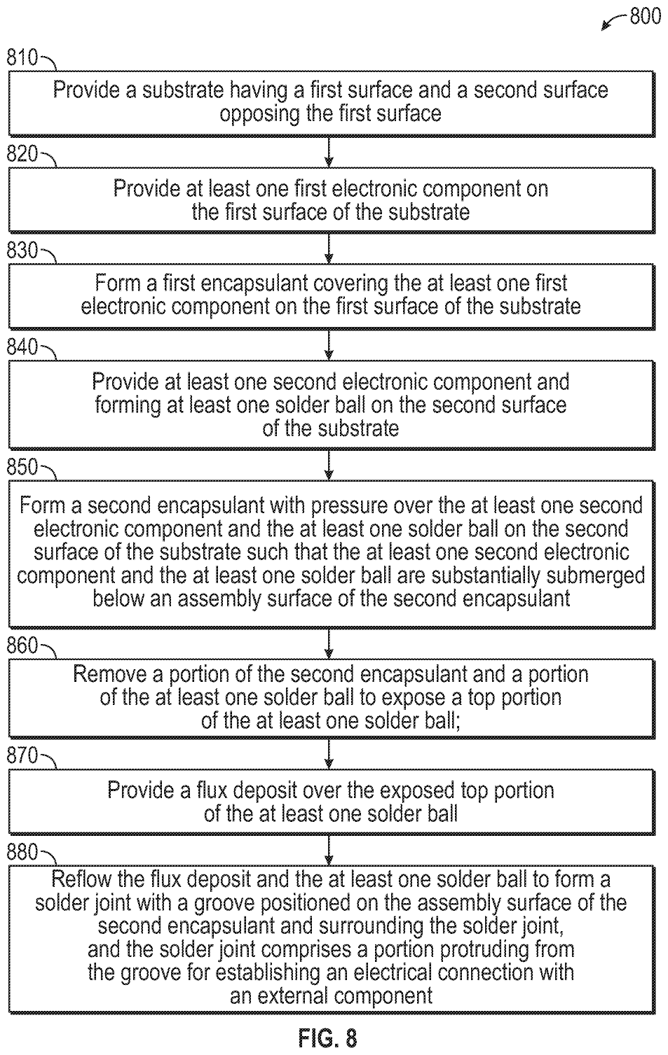

The substrate 110 includes a patterned bottom metal layer 120 and a patterned top metal layer (not shown). The patterned bottom metal layer 120 includes representative contact pads 121 arranged on the bottom surface 110b of the substrate 110, each of the contact pads 121 may be a signal contact pad configured to transmit electrical signals. Electrical contacts, such as solder contacts in the form of solder balls or solder joints 180 are attached to the contact pads 121. The solder joints 180, for example, may include SnAg, SnAgCu, SnCu or SnPb. Other suitable solder materials, which are within the purview of one of ordinary skill in the art having had the benefit of the present disclosure, may also be useful. In accordance with a representative embodiment, one or more grooves or depressions 170 are positioned on the second assembly surface 160a of the second encapsulant as shown in FIG. 1A, FIG. 1B and FIG. 1C. In this disclosure, the term “groove” and “depression” may be used interchangeably. As illustrated in the current and subsequent embodiments, the depressions 170 comprise a curvature surface and may have a hemispherical shape. The curvature surface of the depressions 170 may be attributed to the manufacturing process as illustrated in FIG. 5, FIG. 6, FIG. 7 and FIG. 8 due to the reason that the second encapsulant 160 is molded on an intermediary solder ball (not shown). The intermediary solder ball (not shown) is then reballed to form the solder joints 180 as shown in FIG. 1A. In one embodiment, a portion 180p of the solder joints 180 protrudes from the grooves or depressions. For example, a portion 180p of the solder joints 180 protrudes from the grooves in a direction substantially perpendicular to the second assembly surface 160a. The solder joints 180 are for establishing electrical connections with an external component 190. For example, in a final product where the electronic assembly 100 is attached on the mother board 490 (See FIG. 4) of a device, the solder joints 180 may be melted during a solder reflow process to establish an electrical contact 480 with the mother board 490 (See FIG. 4). The portion 180p of the solder joints, for example, includes a stand-off height which is sufficient for assembling onto the external component 190. The solder joint 180, for example, includes a curved ball surface 180a prior to assembly to the external component 190.

Referring to FIG. 1B, the groove or depression 170 includes a curved groove surface 170a. The depression 170, for example, may be a substantially hemispherical depression positioned on the second assembly surface 160a. In a representative embodiment, the curved ball surface 180a of the solder joint 180 is steeper than the curved groove surface 170a of the groove 170 so as to form a gap 175 between the solder joint 180 and the groove 170. The groove 170, for example, includes a flare angle (θ). In one example, a slanted line A-A′ is a virtual line drawn as a representation of how the curved groove surface 170a relates to the bottom surface 110b of the substrate. The slanted line A-A′ may be drawn on a cross sectional view of the second encapsulant 160 as shown in FIG. 1B. The slanted line A-A′, for example, may be a line connecting the end tips of the curved groove surface as shown in FIG. 1B. The flare angle (θ), for example, is measured from the bottom surface 110b of the substrate to the slanted line A-A′ as shown in FIG. 1B. In one embodiment, the flare angle (θ) may be less than or equal to 120°. Compared to other assemblies where a laser ablation technology is employed, the flare angle (θ) shown in FIG. 1B is steeper, and hence, smaller flare angle (θ). This enables a neighboring solder joint 180 to be placed nearer. The smaller pitch between the adjacent solder joints 180 is illustrated in the subsequent paragraph.

For example, the solder joint 180, as shown, has a ball diameter (D). In some embodiments, the gap spacing (g) between the solder joint 180 and the groove 170 may be less than a quarter of the ball diameter (D). In some other embodiments, the gap spacing (g) between the solder joint 180 and the groove 170 may be less than one fifth of the ball diameter (D). As shown, the second electronic component 140 includes a component height (h) and the groove 170 includes a groove diameter (GD). In one embodiment, the groove diameter (GD) is larger than the ball diameter (D). The groove 170 may be formed from an intermediary solder ball 580 (See FIG. 5) which exists during the manufacturing process. For ease of understanding, the size of the intermediary solder ball 580 is illustrated as dotted line in FIG. 1B. The groove 170, for example, may have a hemispherical shape with a groove diameter (GD) that is defined by the size of the intermediary solder ball 580. In the event where the grinding depth has a higher value than the radius of the intermediary solder ball 580, the groove diameter (GD) may be attributed by the grinding depth as will be described with respect to FIG. 5 later. Further, in some embodiments, the groove 170 comprises a groove depth (d) measured from the second assembly surface 160a which is about more than 60% of a thickness (T) of the second encapsulant 160. In some embodiments, more than approximately 70% of the solder joint is submerged within the groove below the second assembly surface 160a. Other suitable groove depth relative to the thickness of the second encapsulant, gap spacing relative to the ball diameter (D), and groove diameter (GD) relative to the ball diameter (D) may also be useful depending on process variations and design considerations.

The solder joint 180 and the curved groove surface 170a respectively may comprise a substantially smooth surface which is devoid of residue material of the second encapsulant 160. For example, in the embodiment shown in FIG. 1B, the curved groove surface 170a and the curved ball surface 180a respectively is a smooth surface substantially devoid of resin and/or filler material of the second encapsulant 160. The substantially smooth surface may be attributed by the manufacturing process illustrated in FIG. 5, FIG. 6, FIG. 7 and FIG. 8 which is devoid of the step of laser ablation. Referring to FIG. 1C, the solder joint 180 is positioned substantially at a center of the groove 170. The solder joints 180, for example, are substantially aligned within the center of the grooves 170. Further, adjacent grooves 170 may be placed as close with one another allowing for fine pitch array and small form factor to be achieved. The spacing (s) between adjacent grooves 170, for example, may be less than 60 μm.

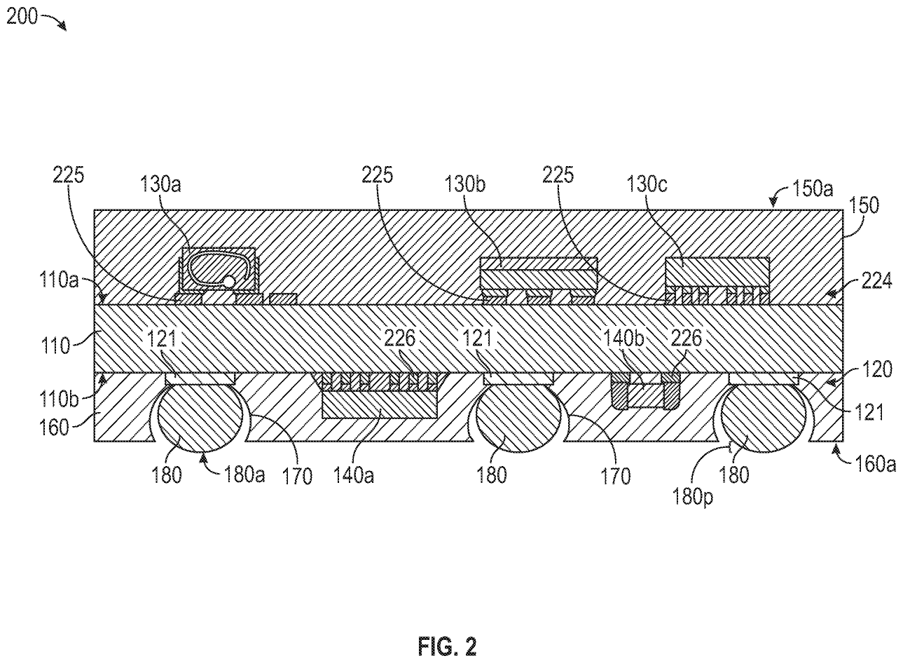

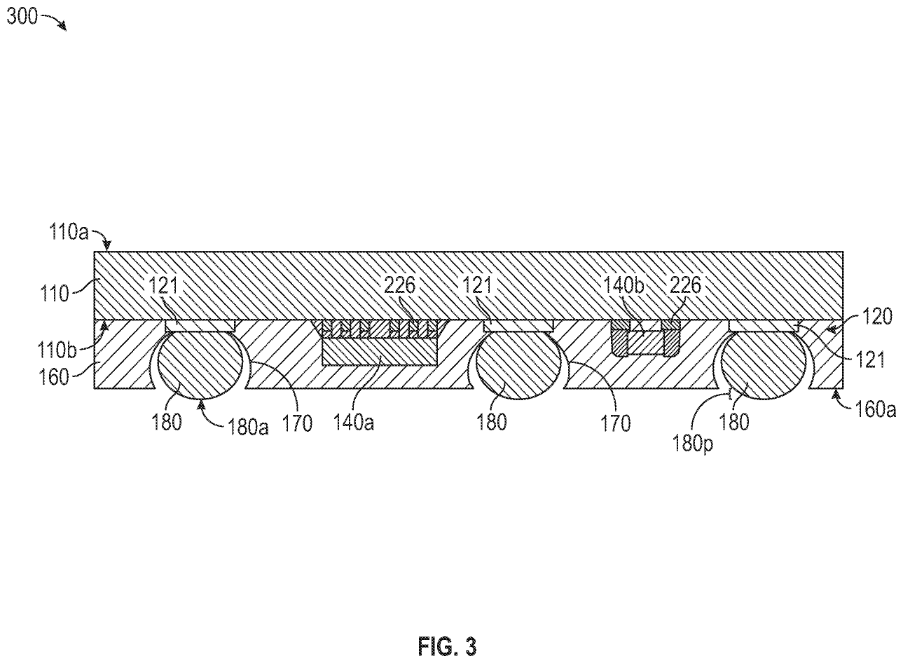

The functional block diagram shown in FIG. 1A is illustrated without associating the electronic assembly 100 with a specific arrangement, or being fabricated using a specific process. Subsequent embodiments may show drawings illustrating the similar electronic assembly using a specific arrangement or using a specific process. All components shown in subsequent embodiments that are in common with the electronic assembly 100, such as features having the same reference numerals, may share similar characteristics or may be identical. Further elaboration of the various features and advantages as discussed herein with respect to FIGS. 1A, 1B and 1C can be found in the discussion on FIG. 2, FIG. 3, FIG. 4 and FIG. 5 below.

FIG. 2 is an illustrative cross-sectional view of an electronic assembly 200 in accordance with a representative embodiment. FIG. 2, for example, includes common elements as already discussed with respect to FIG. 1A, FIG. 1B and FIG. 1C. In the interest of brevity, common elements or elements with the same reference numerals will not be described or described in detail. The electronic assembly 200 includes a substrate 110. The substrate 110 may be formed of any material compatible with semiconductor processes, such as silicon (Si), gallium arsenide (GaAs), indium phosphide (InP), glass, sapphire, alumina, epoxy, bismaleimide triazine (BT), prepreg composites, reinforced or non-reinforced polymer dielectrics and the like, for example.

The substrate 110 includes a patterned top metal layer 224. The patterned top metal layer 224 includes representative component pads 225 arranged on a top (first) surface 110a of the substrate. It is understood that the component pads 225 may include alternative numbers and arrangements, depending on design and configuration requirements. For purposes of illustration, representative first set of electronic components include first, second and third flip chip dies 130a, 130b and 130c (or flip chip integrated circuits, or more generally, electronic components) mounted to the component pads 225. Although FIG. 2 shows the electronic assembly 200 as having three flip chip components, it is understood that the electronic assembly may contain different numbers and/or types of electronic components, including wirebond die, surface mount technology (SMT) component, or a combination thereof without departing from the scope of the present teachings.

The patterned bottom metal layer 120 includes representative contact pads 121 and representative component pads 226 arranged on the bottom (second) surface 110b of the substrate 110, each of the contact pads 121 and component pads 226 may be a signal contact pad configured to transmit electrical signals. The contact pads 121 may be BGA pads, for example, although other types of contact pads, such as LGA pads and DGA pads, and/or pins may be incorporated without departing from the scope of the present teachings. The contact pads 121 are arranged in an array, for purpose of illustration. It is understood that the contact pads 121 may include suitable numbers and arrangements, depending on design and configuration requirements. The contact pads 121 and the component pads 225 and 226 may comprise conductive materials compatible with semiconductor processes, such as gold (Au), silver (Ag), aluminum (Al) or copper (Cu), for example. For purposes of illustration, representative second set of electronic components include a flip chip die 140a (or electronic component) and a SMT passive component 140b (or electronic component) mounted to the component pads 226. Although FIG. 2 shows the electronic assembly 200 as having two components mounted to the bottom surface 110b of the substrate, it is understood that the electronic assembly may contain different numbers and/or types of electronic components, including wirebond die, SMT component, or a combination thereof without departing from the scope of the present teachings. Examples of other components that may be mounted to the top and bottom surfaces of (or embedded within) the substrate 110 include power amplifiers, filters, transducers, complementary metal-oxide semiconductor (CMOS) circuits, integrated silicon-on-insulator (SOI) circuits and the like, although the various embodiments are not limited to these examples.

A first encapsulant 150 is disposed over the top surface 110a of the substrate 110 and substantially encapsulates the flip chip dies 130a, 130b and 130c. A second encapsulant 160 is disposed over the bottom surface 110b of the substrate 110 and substantially encapsulates the electronic components 140a and 140b. For purpose of illustration, the first encapsulant 150 and the second encapsulant 160 completely surround the first set of electronic components and the second set of electronic components. In various embodiments, the first encapsulant 150 and the second encapsulant 160 may partially surround the first set of electronic components and the second set of electronic components, leaving top portions of the first and second set of electronic components exposed. The first encapsulant 150 and the second encapsulant 160 include a mold compound that may be formed of a reinforced or non-reinforced resin, for example, generally protecting the first set of electronic components 130a, 130b and 130c and the second set of electronic components 140a and 140b, and providing additional structural support to the electronic assembly 200. The mold compound, for example, may include epoxy resin, silicone resin, glass resin, acrylics or polyimides. Other suitable mold compound materials, which are within the purview of one of ordinary skill in the art having had the benefit of the present disclosure, may also be useful. In various embodiments, the mold compound may hermetically seal the first set of electronic components 130a, 130b and 130c and the second set of electronic components 140a and 140b within the electronic assembly 200.

Referring to FIG. 2, electrical contacts, such as solder contacts in the form of solder balls or solder joints 180 are attached to the contact pads 121. The solder joints, for example, may include SnAg, SnAgCu, SnCu or SnPb. Other suitable solder materials, which are within the purview of one of ordinary skill in the art having had the benefit of the present disclosure, may also be useful. In accordance with a representative embodiment, one or more grooves or depressions 170 are positioned on the second assembly surface 160a of the second encapsulant 160. The grooves 170 and the solder joints 180 include the same configuration and characteristics as that described in FIG. 1A, FIG. 1B and FIG. 1C. Thus, the details of the grooves and solder joints will not be repeated herein. As shown, a portion 180p of the solder joints 180 protrudes from the grooves or depressions 170. For example, a portion 180p of the solder joints 180 protrudes from the grooves in a direction substantially perpendicular to the second assembly surface 160a for establishing an electrical connection with an external component (not shown). The external component, for example, may be a mother board or PCB of an electronic device. The electronic device, for example, may include a mobile device, a communication device or a computing device. The external component may provide a physical support for the electronic assembly 200 and other circuit elements (not shown) disposed on the external component. In addition to providing physical support to the electronic assembly 200, the external component may also provide electrical connectivity between the electronic assembly with other circuit elements on and/or within the external component.

FIG. 3 is an illustrative cross-sectional view of an electronic module 300 in accordance with another representative embodiment. FIG. 3, for example, includes common elements as already discussed with respect to FIG. 1A, FIG. 1B, FIG. 1C and FIG. 2. In the interest of brevity, common elements or elements with the same reference numerals will not be described or described in detail. In the interest of brevity, common features or elements having the same reference numerals may not be described or described in detail. The description below primarily focuses on the differences between the electronic module 300 shown in FIG. 3 and the electronic assembly 200 shown in FIG. 2.

The electronic module 300 of FIG. 3 differs from the electronic assembly 200 of FIG. 2 in that the electronic module 300 includes electronic components 140a and 140b disposed on the bottom surface 110b of the substrate 110 while the top surface 110a of the substrate 110 is exposed. The electronic components 140a and 140b are substantially encapsulated by an encapsulant 160. For example, the electronic components 140a and 140b are completely encapsulated within the encapsulant 160 which is disposed on the bottom surface 110b of the substrate. The encapsulant 160, as shown, includes an assembly surface 160a which is suitable for stacking on to an external surface of an external component (not shown). For purpose of illustration, there is no electronic component and no encapsulant disposed on the top surface 110a of the substrate. However, it is understood that one or more electronic components may be stacked on top of the top surface 110a of the substrate with or without encapsulant thereon.

Similar to the electronic assembly 100 of FIG. 1A and the electronic assembly 200 of FIG. 2, the electronic module 300 of FIG. 3 also includes electrical contacts, such as solder contacts in the form of solder balls or solder joints 180 being attached to the contact pads 121. In accordance with a representative embodiment, one or more grooves or depressions 170 are positioned on the assembly surface 160a of the encapsulant 160. The grooves 170 and the solder joints 180 as shown in FIG. 3 include the same configuration and characteristics as that described in FIG. 1B. For example, the solder joints 180 are positioned within the depressions 170, which are substantially hemispherical in the present example, for establishing an electrical connection with an external component (not shown).

FIG. 4 is an illustrative cross-sectional view of a portion of an electronic device 400 in accordance with a representative embodiment. FIG. 4, for example, includes common elements as already discussed with respect to FIG. 1A, FIG. 1B, FIG. 1C, FIG. 2 and FIG. 3. In the interest of brevity, common elements or elements with the same reference numerals will not be described or described in detail.

The electronic device 400, for example, may be a mobile device, a communication device or a computing device. FIG. 4 shows an illustrative portion of an electronic device, particularly where an electronic assembly or an electronic module such as that described in FIG. 1A, FIG. 2 or FIG. 3 is mounted onto an assembly substrate 490. The assembly substrate 490 includes an assembly surface 490a of which an electronic module is mounted thereon. The assembly substrate 490 may be a mother board of a mobile device such as a phone, or a notebook, which is configured to receive various electronic assemblies. In FIG. 1A, FIG. 2 or FIG. 3, the assembly substrate 490 is shown as an external component 190.

Referring to FIG. 4, the module substrate 110 includes a bottom surface 110b. A module electronic component 140 and a module encapsulant 160 surrounding the module electronic component 140 are disposed on the surface 110b of the module substrate 110. As shown, the encapsulant 160 includes a module assembly surface 160a for stacking onto the assembly surface 490a. Similar to that described in FIG. 1A, FIG. 1B, FIG. 1C, FIG. 2 and FIG. 3, the module assembly surface 160a also includes at least one encapsulant depression 170 having a curved groove surface 170a positioned on the module assembly surface. The solder joint 180 is positioned substantially within the at least one encapsulant depression 170 such that the solder joint 180, as shown, is configured to electrically connect the module substrate 110 to the assembly substrate 490. The solder joint 180, in one embodiment, comprises substantially solder material such that the solder joint 180 is devoid of any encapsulant residue. Details of how the solder joints and depressions being devoid of any encapsulant residue can be found in the discussion on FIG. 5, FIG. 6, FIG. 7 and FIG. 8 below.

In the embodiment shown in FIG. 4, the solder joints 480 may completely fill up the depressions 170 of the second encapsulant 160. In contrast, the electronic assemblies and modules 100-300 shown in FIG. 1A, FIG. 2 and FIG. 3 have a gap between the solder joints 180 and the depressions 170. This may be due to the fact that the solder joints 480 may have gone through a reflow process in which the solder joints 480 are melted. The melted solder material fills up the depressions 170. However, in some embodiments, the melted solder material may not fill up the depressions 170 completely. Therefore, there may be a space between the solder joints 480 and the depressions 170. In some other embodiments where the assemblies and modules 100-300 shown in FIG. 1A, FIG. 2 and FIG. 3 are attached via other means, the electronic device 400 may comprise a gap between the solder joint 480 and the depressions 170 similar to the gap 175 shown in FIG. 1A.

FIG. 5 shows illustrative cross-sectional views of a method 500 of fabricating an electronic assembly according to a representative embodiment.

Referring to step 510, a substrate 110 is provided. The substrate 110 includes a patterned top metal layer 224 disposed on a top surface 110a and a patterned bottom metal layer 120 disposed on a bottom surface 110b of the substrate 110. The substrate 110 may be formed of any material compatible with semiconductor processes, such as silicon (Si), gallium arsenide (GaAs), indium phosphide (InP), glass, sapphire, alumina, epoxy, bismaleimide triazine (BT), prepreg composites, reinforced or non-reinforced polymer dielectrics and the like, for example. Internal electronic circuitry (not shown) may be included in the substrate 110, such as internal metal layers (e.g., signal and/or ground layers), traces and/or vias interconnecting various internal metal layers, to provide unique benefits for any particular situation or to meet application specific design requirements of various implementations, without departing from the scope of the present teachings.

The patterned top metal layer 224 and the patterned bottom metal layer 120 may be fabricated at substantially the same time. For example, electroless copper (Cu) may be plated as a blanket film on the bottom and top surfaces of the substrate 110. Photo resist may then be applied to both the bottom and top copper (Cu) plating, and exposed to create openings corresponding to desired shapes and locations of the representative component pads 225 and 226 and contact pads 121. The pads are electrolytically plated on both sides of the substrate 110 where the electroless copper (Cu) is exposed (in the photo resist open areas). The photo resist is stripped, and the thin electroless copper (Cu) layer is etched from all surfaces, leaving the outer layer copper (Cu) pads. That is, the outer layer copper (Cu) pads include the representative component pads 225 and 226 and the representative contact pads 121. The contact pads 121 may be signal contact pads configured to transmit electrical signals, and may be BGA pads, for example, although other numbers and types of contact pads, such as LGA pads and DGA pads, and/or pins may be incorporated without departing from the scope of the present teachings.

For purpose of illustration, flip chip dies 130a, 130b and 130c are attached to the component pads 225, respectively as shown in step 510. The flip chip dies 130a, 130b and 130c may be attached using any compatible attachment method, such as placing copper pillars on one surface of the flip chip dies 130a, 130b and 130c on solder balls applied to the component pads 225, respectively, and reflowing the solder. In the event where wirebond die and/or SMT component are attached to the component pads, any suitable compatible methods for attaching these wirebond die and SMT component may be used.

Referring to step 510, an encapsulant material such as a first mold compound is disposed over the substrate 110 and the electronic components arranged thereon (e.g., the flip chip dies 130a, 130b and 130c). The first mold compound may be formed of a reinforced or non-reinforced resin, for example. The first mold compound, for example, may include epoxy resin, silicone resin, glass resin, acrylics or polyimides. Other suitable mold compound materials, which are within the purview of one of ordinary skill in the art having had the benefit of the present disclosure, may also be useful. The first mold compound may be applied using any process compatible with fabrication of semiconductor devices, such as injection molding, transfer molding, film assisted molding or compression molding, for example. In various embodiments, the first mold compound may be applied in a liquid or viscous state, and then allowed to set to provide the solid mold compound thereby forming a first encapsulant 150. The first encapsulant 150 generally protects the electronic components 130a, 130b and 130c and provides additional structural support.

Referring to step 520, the method 500 continues by assembling electronic components on a bottom surface 110b of the substrate 110. For purpose of illustration, a flip chip die 140a and a SMT component 140b are attached to the bottom surface 110b of the substrate 110. The flip chip die 140a may be attached using any compatible attachment method, such as placing copper pillars on one surface of the flip chip die 140a on solder balls applied to the pads on the bottom surface of the substrate, respectively, and reflowing the solder. The SMT component 140b may be attached using any compatible attachment method, such as placing the SMT component 140b on solder balls applied to the pads and reflowing the solder.

The method 500 continues by placing a first stencil (not shown) over the bottom surface 110b of the substrate 110. The first stencil defines multiple first apertures (not shown) that correspond to contact pads 121 on the bottom surface 110b of the substrate. Solder paste is applied through the first apertures in the first stencil to provide corresponding solder paste deposits on the contact pads 121, after which the first stencil is removed. This operation may be referred to as solder paste printing. The solder paste comprises a mixture of solder and flux in predetermined proportions.

The solder paste deposits are then reflowed to form corresponding solder balls 580 on the contact pads 121, respectively. The solder balls 580, for example, may also be referred to as an intermediary solder ball in this disclosure. Reflowing the solder paste deposits may include temporarily applying heat to the structure, including the substrate, the contact pads and the solder paste deposits, for example, causing the solder paste deposits to melt. For example, the structure may be heated by placing it in a heated environment, such as a reflow oven. The heated environment may contain an excess of nitrogen to enable better wetting characteristics of the solder balls, and to prevent oxidation of solder balls at high temperatures. When the solder paste deposits are in the melted or molten state, they become substantially rounded (effectively forming a half circle or half ellipse). The solder paste deposits are then allowed to cool and solidify into the solder balls 580, having substantially rounded top surfaces, attached to (e.g., adhered to or bonded with) the contact pads 121, respectively.

In an embodiment, flux cleaning may be performed after reflowing the solder paste deposits in order to remove excess or residual flux of the solder paste from the substrate 110. The flux cleaning may be a wet process, for example, although various flux cleaning processes may be incorporated without departing from the scope of the present teachings.

The method 500 continues by applying an encapsulant material such as a second mold compound over the bottom surface 110b of the substrate 110 and the electronic components arranged thereon (e.g., the flip chip die 140a and the SMT component 140b). The second mold compound, referred to as the second encapsulant 160, may be formed of a reinforced or non-reinforced resin, for example. The second mold compound, for example, may include epoxy resin, silicone resin, glass resin, acrylics or polyimides. Other suitable mold compound materials, which are within the purview of one of ordinary skill in the art having had the benefit of the present disclosure, may also be useful. The second mold compound may be applied using any process compatible with fabrication of semiconductor devices. In a representative embodiment, the second mold compound may be applied using techniques such as injection molding, or transfer molding as illustrated in step 530a. In such case, the electronic components 140a and 140b and the solder balls 580 are substantially embedded within the second mold compound. The electronic components 140a and 140b, and the solder balls 580, for example, are completely submerged below an assembly surface 160a of the second encapsulant 160 as shown in step 530a.

In another representative embodiment, the second mold compound may be applied using an alternate technique such as film assisted molding as illustrated in step 530b. In such case, the electronic components 140a and 140b are substantially embedded within the second mold compound 160 while the solder balls 580 are partially exposed. The electronic components 140a and 140b, for example, are completely submerged below an assembly surface 160a of the second encapsulant 160 while a top portion of the solder balls 580 are extended beyond the assembly surface 160a of the second encapsulant 160 as shown in step 530b.

In yet another representative embodiment, the second mold compound may be applied using an alternate technique such as compression molding or over-pressed molding as illustrated in step 530c. In such case, the electronic components 140a and 140b and the solder balls 580 are substantially embedded within the second mold compound 160. The electronic components 140a and 140b, and the solder balls 580, for example, are completely submerged below an assembly surface 160a of the second encapsulant 160 as shown in step 530c. Further, the solder balls 580 may be squeezed and slightly deformed due to the pressure applied during the compression molding.

In various embodiments shown in step 530a, 530b or 530c, the second mold compound may be applied in a liquid or viscous state, and then allowed to set to provide the solid mold compound to form the second encapsulant 160. The second encapsulant 160 generally protects the electronic components and provides additional structural support.

The method 500 continues to remove portions of the molded structure. In one embodiment, a portion of the second encapsulant 160 and a portion of the solder balls 580 are removed, exposing top portion of the solder balls 580 as shown in step 540. A portion of the molded structure and a portion of the solder balls, in one embodiment, are removed by a mold grinding technique. Other suitable techniques may also be used to thin the molded structure to a suitable thickness, depending on the desired thickness of the electronic module or assembly. As shown, the second encapsulant is thinned to a desired thickness, resulting in a final thickness (T) while the exposed portion of the solder balls 580 includes a top surface 580a that is substantially co-planar with an assembly surface 160a of the second encapsulant 160.

Referring to step 550, the method 500 continues to place a second stencil (not shown) over the bottom surface 110b of the substrate 110. The second stencil defines multiple second apertures (not shown) that correspond to the contact pads 121 on the bottom surface 110b of the substrate. In an embodiment, the second apertures in the second stencil are substantially the same (e.g., in size, shape and location) as the first apertures in the first stencil.

In step 550, flux is applied through the second apertures in the second stencil to provide corresponding flux paste deposits on the substantially planarized solder balls 580 which are embedded within the second encapsulant 160, after which the second stencil is removed. This operation may be referred to as flux printing. The flux deposits and the solder balls 580 are reflowed in step 550 to form solder joints 180 as illustrated in FIG. 1A, FIG. 1B, FIG. 1C, FIG. 2 and FIG. 3. Reflowing the flux deposits and the solder balls 580 which are embedded within the second encapsulant 160 may include temporarily applying heat to the structure, including the substrate, the contact pads, the solder balls, the flux deposits, for example, causing a portion of the solder balls 580 and flux deposit formed thereon to melt, as discussed above. In one embodiment, a portion of the solder balls 580 (particularly the exposed top portions and portions of the solder balls 580 approximating the assembly surface 160a of the second encapsulant) is melted when the heat is applied. When the heat is removed, the portion of the melted solder balls is drawn to combine with the flux deposits and thereafter solidifies and “reballs” to form the solder joints 180. Significantly the tacky textures of the flux deposits draw or lift a portion of the solder ball 580 approximating the assembly surface 160a, thereby leaving a gap 175 in between the groove or depression 170 which surrounds the solder joint 180 on the assembly surface 160a of the second encapsulant 160. In an embodiment, flux cleaning may be performed after reflowing the flux deposits and the solder balls in order to remove excess or residual flux from the substrate 110.

The grooves 170 and the solder joints 180 include the same configuration and characteristics as that described in FIG. 1B. Thus, the details of the grooves and solder joints will not be repeated herein. As shown, a portion 180p of the solder joints 180 protrudes from the grooves or depressions. For example, a portion 180p of the solder joints 180 protrudes from the grooves in a direction substantially perpendicular to the second assembly surface 160a for establishing an electrical connection with an external component (not shown). The external component, for example, may be a mother board or PCB of an electronic device.

The method 500 as described results in several advantages. For example, the gap 175 in between the solder joints 180 and the grooves or depressions 170 are naturally formed during the reballing process of the solder joints 180. Thus, the solder joints are positioned substantially at a center of the grooves 170, avoiding any misalignment problems relative to the contact pads. In other words, the method 500 shown in FIG. 5 does not require any alignment during the reballing process. However, other technology, such as those using laser ablation technique, to shape the solder joints 180 may require further alignment. Further, the solder joint 180 and the curved groove surface 170a respectively includes a smooth surface devoid of residue material of the second encapsulant. For example, the curve groove surface 170a and the curved ball surface 180a respectively is a smooth surface substantially devoid of resin and/or filler material of the second encapsulant 160. Since the groove diameter (GD) is substantially the same as the original diameter of the solder ball 580 as deposited, adjacent solder balls 580 can be placed as close with one another allowing for fine pitch array and small form factor to be achieved.

In another method which is not shown herein, the step 530a or 530c may be modified by using another technique to remove a portion of the molded structure so as to expose top portions of the solder balls. In this alternate method, a portion of the molded structure is removed by a laser ablation technique. The laser ablation technique also forms a groove surrounding the solder ball portion. The groove formed by the laser ablation technique, for example, may have a slanted surface and may have some residue material of the second encapsulant contained therein. Similarly, the exposed portion of the solder balls may have some residue material of the second encapsulant deposited thereon due to the laser ablation technique.

FIG. 6 shows a flow chart illustrating a method 600 of manufacturing an electronic module in accordance with an embodiment of the present disclosure. It should be appreciated that the steps of method 600 can be performed in any order and they may include one or more of the process steps and materials depicted and discussed in connection with FIG. 5. Moreover, one of more of the steps depicted in FIG. 6 may correspond to optional steps or may correspond to steps that can be performed in combination with other steps.

The method 600 begins by providing a substrate (step 610). The substrate includes a first surface and a second surface opposing the first surface. The first surface may be referred to as the top surface and the second surface may be referred to as the bottom surface of the substrate. The substrate, for example, may be a PCB. At least one first electronic component is provided on the first surface of the substrate (step 620). A first encapsulant substantially covering the at least one first electronic component is formed on the first surface of the substrate (step 630).

The method 600 continues by providing at least one second electronic component and forming at least one solder ball on the second surface of the substrate (step 640). A second encapsulant is formed over and substantially covers the at least one second electronic component and the at least one solder ball on the second surface of the substrate (step 650). In this step, an over-molding technique may be used of which the second encapsulant covers the entire second electronic component and the solder ball such that the second electronic component and the at least one solder ball are completely submerged below an assembly surface of the second encapsulant.

The method 600 continues by removing a portion of the second encapsulant and a portion of the at least one solder ball to expose a top portion of the at least one solder ball (step 660). In this step, a mold grinding technique may be utilized to thin the second encapsulant to a desired thickness. The mold grinding process also exposes a portion of the at least one solder ball such that a top surface of the exposed portion of the solder ball is substantially co-planar with an assembly surface of the second encapsulant. It should be appreciated that other suitable techniques may be employed to remove a portion of the second encapsulant and the at least one solder ball to the desired thickness.

A flux deposit is then provided over the exposed portion of the at least one solder ball (step 670). The method 600 continues by reflowing the flux deposit and the at least one solder ball to form a solder joint with a groove positioned on the assembly surface of the second encapsulant and surrounding the solder joint (step 680). The solder joint includes a portion protruding from the groove. For example, a portion of the solder joint protrudes from the groove in a direction substantially perpendicular to the assembly surface for establishing an electrical connection with an external component.

FIG. 7 shows a flow chart illustrating a method 700 of manufacturing an electronic module in accordance with another embodiment of the present disclosure. It should be appreciated that the steps of method 700 can be performed in any order and they may include one or more of the process steps and materials depicted and discussed in connection with FIG. 5. Moreover, one of more of the steps depicted in FIG. 7 may correspond to optional steps or may correspond to steps that can be performed in combination with other steps.

The method 700 begins by providing a substrate (step 710). The substrate includes a first surface and a second surface opposing the first surface. The first surface may be referred to as the top surface and the second surface may be referred to as the bottom surface of the substrate. The substrate, for example, may be a PCB. At least one first electronic component is provided on the first surface of the substrate (step 720). A first encapsulant substantially covering the at least one first electronic component is formed on the first surface of the substrate (step 730).

The method 700 continues by providing at least one second electronic component and forming at least one solder ball on the second surface of the substrate (step 740). A second encapsulant is formed over and substantially covers the at least one second electronic component and partially covers the at least one solder ball on the second surface of the substrate (step 750). In this step, a film assisted molding technique may be used of which the second encapsulant covers the entire second electronic component while partially covering the solder ball such that a top portion of the at least one solder ball is exposed. In such case, the second encapsulant is provided in accordance with the desired thickness without a further thinning process.

A flux deposit is then provided over the exposed portion of the at least one solder ball (step 760). The method 700 continues by reflowing the flux deposit and the at least one solder ball to form a solder joint with a groove positioned on the assembly surface of the second encapsulant and surrounding the solder joint (step 770). The solder joint includes a portion protruding from the groove. For example, a portion of the solder joint protrudes from the groove in a direction substantially perpendicular to the assembly surface for establishing an electrical connection with an external component.

FIG. 8 shows a simplified flow chart illustrating a method 800 of manufacturing an electronic module in accordance with yet another embodiment of the present disclosure. It should be appreciated that the steps of method 800 can be performed in any order and they may include one or more of the process steps and materials depicted and discussed in connection with FIG. 5. Moreover, one of more of the steps depicted in FIG. 8 may correspond to optional steps or may correspond to steps that can be performed in combination with other steps.

The method 800 begins by providing a substrate (step 810). The substrate includes a first surface and a second surface opposing the first surface. The first surface may be referred to as the top surface and the second surface may be referred to as the bottom surface of the substrate. The substrate, for example, may be a PCB. At least one first electronic component is provided on the first surface of the substrate (step 820). A first encapsulant substantially covering the at least one first electronic component is formed on the first surface of the substrate (step 830).

The method 800 continues by providing at least one second electronic component and forming at least one solder ball on the second surface of the substrate (step 840). A second encapsulant is formed over and substantially covers the at least one second electronic component and the at least one solder ball on the second surface of the substrate (step 850). In this step, a compression molding technique may be used of which pressure may be applied during formation of the second encapsulant over the entire second electronic component and the solder ball such that the second electronic component and the at least one solder ball are completely submerged below an assembly surface of the second encapsulant. In such case, the solder ball may be squeezed and slightly deformed.

The method 800 continues by removing a portion of the second encapsulant and a portion of the at least one solder ball to expose a top portion of the at least one solder ball (step 860). In this step, a mold grinding technique may be utilized to thin the second encapsulant to a desired thickness. The mold grinding process also exposes a portion of the at least one solder ball such that a top surface of the exposed portion of the solder ball is substantially co-planar with an assembly surface of the second encapsulant. It should be appreciated that other suitable techniques may be employed to remove a portion of the second encapsulant and the at least one solder ball to the desired thickness.

A flux deposit is then provided over the exposed portion of the at least one solder ball (step 870). The method 800 continues by reflowing the flux deposit and the at least one solder ball to form a solder joint with a groove positioned on the assembly surface of the second encapsulant and surrounding the solder joint (step 880). The solder joint includes a portion protruding from the groove. For example, a portion of the solder joint protrudes from the grooves in a direction substantially perpendicular to the assembly surface for establishing an electrical connection with an external component.

The various components, structures and parameters are included by way of illustration and example only and not in any limiting sense. In view of this disclosure, those skilled in the art can implement the present teachings in determining their own applications and needed components, materials, structures and equipment to implement these applications, while remaining within the scope of the appended claims.

What is claimed:

1. An electronic assembly comprising:
a substrate having a first surface and a second surface opposing the first surface;
a first electronic component disposed on the first surface of the substrate, and being substantially encapsulated by a first encapsulant on the first surface of the substrate;
a second electronic component disposed on the second surface of the substrate, being substantially encapsulated by a second encapsulant on the second surface of the substrate, wherein the second electronic component is completely submerged below a second assembly surface of the second encapsulant;
a groove positioned on the second assembly surface of the second encapsulant; and
a solder joint having a portion protruding from the groove for establishing an electrical connection with an external component.

2. The electronic assembly of claim 1, wherein the groove comprises a curved groove surface.

3. The electronic assembly of claim 2, wherein the curved grooved surface is a smooth surface substantially devoid of resin and filler material.

4. The electronic assembly of claim 2, wherein the solder joint comprises a curved ball surface.

5. The electronic assembly of claim 4, the curved ball surface is steeper than the curved groove surface so as to form a gap between the solder joint and the groove.

6. The electronic assembly of claim 5, wherein the solder joint has a ball diameter, and wherein the gap between the solder joint and the groove is less than a quarter of the ball diameter.

7. The electronic assembly of claim 5, wherein the solder joint has a ball diameter, and wherein the gap between the solder joint and the groove is less than one fifth of the ball diameter.

8. The electronic assembly of claim 4, wherein the curved ball surface is a smooth surface devoid of resin and filler material.

9. The electronic assembly of claim 1, wherein the groove comprises a flare angle that is less than or equal to 120 degree.

10. The electronic assembly of claim 1, wherein the first encapsulant comprises a flat first assembly surface for receiving an external surface.

11. The electronic assembly of claim 1, wherein:
the groove has a groove diameter; and
the solder joint has a ball diameter, and wherein the groove diameter is larger than the ball diameter.

12. The electronic assembly of claim 1, wherein the solder joint is positioned substantially at a center of the groove.

13. The electronic assembly of claim 1, wherein more than approximately 70% of the solder joint is submerged within the groove below the second assembly surface.

14. The electronic assembly of claim 1 further comprising a plurality of additional grooves and a plurality of additional solder joints positioned on the second assembly surface of the second encapsulant.

15. The electronic assembly of claim 14, wherein the distance between adjacent grooves is less than 60 μm.

16. The electronic assembly of claim 1, wherein the second assembly surface of the second encapsulant is substantially flat for receiving an external flat surface.

17. The electronic assembly of claim 1, wherein the groove comprises a depth which is about more than 60% of a thickness of the second encapsulant.

18. An electronic device comprising:
an assembly substrate having an assembly surface;
an electronic module disposed on the assembly surface, wherein the electronic module comprises
a module substrate having a first surface;
a module encapsulant surrounding a module electronic component on the first surface of the module substrate, wherein the module encapsulant comprises a module assembly surface for stacking onto the assembly surface;
an encapsulant depression having a curved surface positioned on the module assembly surface; and
a solder joint positioned substantially within the encapsulant depression, wherein the solder joint is configured to electrical connect the module substrate to the assembly substrate.

19. The electronic device of claim 18, wherein the solder joint comprises substantially solder material such that the solder joint is devoid of encapsulant residue.

20. An electronic module comprising:
a substrate having a first surface and a second surface opposing the first surface;
a first electronic component disposed on the first surface of the substrate;
a first encapsulant encapsulates the first electronic component within the first encapsulant on the first surface of the substrate, wherein the first encapsulant comprises an assembly surface for stacking on an external surface of an external component;
a substantially hemispherical depression positioned on the assembly surface of the first encapsulant; and
a solder joint positioned within the substantially hemispherical depression for establishing an electrical connection with the external component.
